(19) United States
(12) Patent Application Publication
(10) Pub. No.: US 2026/0190889 A1
(43) Pub. Date: Jul. 2, 2026

(54) SILICON ETCH WITH DOPANT-TYPE SELECTIVITY

(71) Applicant: TOKYO OHKA KOGYO CO., LTD., Kawasaki-shi (JP)

(72) Inventors: Fusayo SAEKI, Beaverton, OR (US); Akira MATSUYAMA, Hillsboro, OR (US)

(21) Appl. No.: 19/420,148

(22) Filed: Dec. 15, 2025

Related U.S. Application Data
(60) Provisional application No. 63/740,164, filed on Dec. 30, 2024.

(51) Int. Cl. H10P 50/64; C09K 13/00

(52) U.S. Cl. CPC H10P 50/642; C09K 13/00

(57) ABSTRACT

An etchant composition offers an etch rate on silicon which is sensitive to a dopant type of the silicon. The etchant composition comprises a water-soluble etchant, one or more water-miscible organic solvents, and one or more surfactants.

### CROSS-REFERENCE TO RELATED APPLICATIONS

The present application claims priority to U.S. Provisional application No. 63/740,164, filed with the United States Patent and Trademark Office on Dec. 30, 2024, the entire content of which is incorporated herein by reference.

### TECHNICAL FIELD

This disclosure relates generally to the technical field of semiconductor-device fabrication and more particularly to semiconductor wet-etch processing.

### BACKGROUND

Semiconductor photolithography is a mature and sophisticated art, which is used to make integrated electronic devices of remarkable sophistication and small feature size. An elementary step in most photolithographic processing is masked etching of semiconductor or dielectric features. In masked etching, a resinous photoresist is applied over a semiconductor wafer and exposed to ultraviolet (UV) light projected through a carefully aligned, optical mask. Selected areas of the photoresist layer are either cured and thereby hardened in the pattern defined by the optical mask, or are degraded by the UV light. A solvent can then be used to remove the uncured or degraded portions of the photoresist, leaving behind a pattern of protected and unprotected areas.

Subsequent processing may vary from one implementation to another. In plasma etching, unprotected areas of the semiconductor wafer or die are subjected to high-energy reagents formed in a plasma. Such agents transform unprotected solid material into gaseous residues. In wet (i.e., solution-phase) etching, the unprotected areas are subjected to corrosive solutions that dissolve the undesired material; the soluble residues are subsequently washed away. In both implementations, subsequent processing typically requires removal of all portions of cured photoresist over the surface of the wafer or die. In wet-etch processing, a suitably formulated solvent composition may be used to that effect.

For example, Patent Document 1 (U.S. Pat. No. 11,180,697B2) discloses an etching solution suitable for the selective removal of polysilicon over silicon oxide from a microelectronic 55 device, which comprises: water; about 1 wt % of neat tetramethyl ammonium hydroxide (TMAH); about 15 wt % to about 20 wt % of monoethanolamine (MEA); about 50 wt % to about 59.5 wt % of ethylene glycol (EG); about 0.5 wt % of 8-hydroxyquinoline (8-HQ); and optionally, a surfactant.

### SUMMARY

One aspect of this disclosure relates to an etchant composition offering an etch rate on silicon which is sensitive to a dopant type of the silicon. The etchant composition comprises a water-soluble etchant, one or more water-miscible organic solvents, and one or more surfactants.

Another aspect of this disclosure relates to a method for etching a surface having a first silicon region which is n-type and a second silicon region differing from the first with respect to dopant type. The method comprises exposing the surface to an etchant composition offering an etch rate on silicon which is sensitive to the dopant type, the etchant composition comprising a water-soluble etchant, one or more water-miscible organic solvents, and one or more surfactants.

This Summary is provided to introduce in simplified form a selection of concepts that are further described in the Detailed Description. This Summary is not intended to identify key features or essential features of the claimed subject matter, nor is it intended to be used to limit the scope of the claimed subject matter. The claimed subject matter is not limited to implementations that solve any or all disadvantages noted in any part of this disclosure.

### BRIEF DESCRIPTION OF THE DRAWINGS

FIG. 1 schematically shows an example lateral resection of a p-type silicon (p-Si) layer.

FIG. 2 schematically shows an example removal of a p-type Si layer.

FIG. 3 shows the molecular structures of some of the chemical compounds appearing in Tables 1A and 1B of this disclosure.

FIG. 4 shows aspects of an example method for etching a surface having a first silicon region which is n-type (n-Si) and a second silicon region differing from the first with respect to dopant type or dopant density.

FIGS. 5 through 7 show aspects of the application of the method of FIG. 4 to semiconductors differing with respect to layer structure and dry-etch patterning.

### DETAILED DESCRIPTION

Hereinafter, an embodiment for carrying out the present invention (hereinafter, simply referred to as “the present embodiment”) will be described in detail. The following present embodiment is an example for describing the present invention, and is not intended to limit the present invention to the following contents. The present invention can be appropriately modified and implemented within the scope of the gist thereof. In addition, the configurations and parameters disclosed in the present specification can be any combination unless otherwise specified. Furthermore, an upper limit and a lower limit of the values disclosed in the present specification can be any combination unless otherwise specified.

Wet-etch processing can provide certain advantages over plasma-etch processing for some uses in semiconductor fabrication. The operational costs may be lower, for instance, because wet-etch tools and chemicals are typically less expensive than plasma-etch tools and chemicals. In contrast to plasma-etch processing, wet-etching processing is enacted at lower temperatures, which may simplify the processing of thermally sensitive materials and structures. Wet-etch processing may also yield cleaner surfaces with less residue relative to plasma-etch processing, where residues from etchant gases and by-products may require additional cleaning protocols. In addition, wet-etching is inherently more isotropic, which can be an advantage in applications where isotropic etching is the most efficient process route to specific morphologies and/or device configurations, or for undercutting sacrificial layers.

Finally, wet-etch processing can offer high etch selectivity for one material over another in scenarios where a plurality of different materials is exposed concurrently to the same etch conditions. Available etchant solutions may etch silicon and silicon oxide, for example, at rates that differ by orders of magnitude. This feature provides functional selectivity for semiconductor etching versus dielectric etching. Other etchant solutions can discriminate between dissimilar semiconductors (e.g., germanium (Ge) versus silicon (Si)) with high selectivity. Still other etchant solutions are available that offer a 17-fold difference in etch rate on the 100 face of silicon relative to the 111 face. Such selectivity can be exploited in order to reduce the number of mask alignments and curing steps necessary in a given fabrication process and/or enable selective removal of unprotected structures, such as undercutting.

The inventors herein have sought to extend the selectivity of wet-etch processing to semiconductor systems in which the material differences between distinct, unprotected areas of a wafer or die are extremely subtle. This includes semiconductor materials presenting the same exposed crystal face but differing only in dopant type. Example approaches are illustrated herein, using silicon as the semiconductor.

Doping introduces impurities into a semiconductor. The impurities enable a space charge to develop within the doped semiconductor, which changes the Fermi level of electrons in the semiconductor relative to the valance- and conduction-band edges.

An n-type doping process adds chemical elements with more than four valence electrons into a silicon lattice. Common n-type dopants include phosphorus (P) and arsenic (As), each with five valence electrons per atom. In effect, each n-type dopant atom adds one electron to the conduction band of silicon.

Typical dopant densities for n-type Si at low to moderate dopant levels are 1015 to 1017 atoms per cubic centimeter (cm³). For many semiconductor applications, such as integrated circuits and transistors, n-type silicon is doped in this range. Typical dopant densities for n-type Si at high dopant levels are 1018 to 1020 atoms/cm³. For applications requiring high electronic conductivity, such as in certain types of power devices or specific high-speed transistors, doping concentrations in this range can be used.

A p-type doping process adds elements with fewer than four valence electrons into the silicon lattice. Common p-type dopants include boron (B), gallium (Ga), indium (In), each with three valence electrons per atom. In effect, each p-type dopant atom adds one hole to the valence band of silicon.

Typical dopant densities for p-type Si at low to moderate dopant levels are 1015 to 1017 atoms/cm³. For many semiconductor applications, such as in integrated circuits and transistors, p-type silicon is doped in this range. Typical dopant densities for p-type Si at high dopant levels are 1018 to 1020 atoms/cm³. For applications requiring high hole conductivity, such as in certain types of power devices or specific high-speed transistors, doping concentrations in this range can be used.

Dopants may be added to silicon by diffusion or by ion implantation. In diffusion the wafer is exposed to a gas containing the dopant atoms at high temperatures (typically between 800 and 1200° C.). The dopants diffuse into the silicon wafer, gradually penetrating the surface and becoming incorporated into the silicon lattice. In ion implantation dopant ions are accelerated in an electric field and directed into the silicon wafer. The ions penetrate the surface and embed themselves in the silicon lattice. This method allows for more precise control of the doping concentration and depth compared to diffusion. After the doping process, the wafer typically undergoes a thermal annealing step. Thermal annealing comprises a heating process that helps to repair the damage caused by ion implantation and activates the dopants by allowing them to occupy the expected positions in the silicon lattice.

Certain portions of a semiconductor device may comprise intrinsic silicon (i-Si), in which the concentration of conduction-band electrons is equal to the concentration of valence band holes. In some examples, silicon of this type may be very pure and not subjected to any n-type or p-type doping process (i.e., non-doped or ‘undoped’). In other examples, i-Si may be ‘intrinsically doped’, which means that n-type and p-type dopants are present in approximately equal (and typically low) concentrations, such that the Fermi level of electrons in the silicon is about the same as in non-doped silicon. The term ‘dopant type’ as used herein includes p-type, n-type, i-type, and undoped silicon.

Polycrystalline silicon (poly-Si) comprises a plurality of relatively small silicon crystals, as opposed to a wafer cut from a monocrystalline boule. In some instances, poly-Si may be used to form thin-film transistors, solar cells, as a gate material in metal-oxide-semiconductor (MOS) devices, or in flexible microelectronics.

Amorphous silicon (a-Si) is a non-crystalline form of silicon that differs from the crystalline silicon used in most semiconductor applications. Amorphous silicon lacks a long-range periodic atomic arrangement, resulting in somewhat different electrical properties relative to crystalline silicon. For instance, amorphous silicon has a larger band gap than crystalline silicon. Amorphous silicon is usually deposited as a thin film using techniques such as chemical vapor deposition (CVD) (e.g. plasma enhanced CVD (PECVD)). Amorphous silicon is often deposited in thin layers, which makes it suitable for use in flexible substrates and in various electronic devices. Generally speaking, a-Si can be doped. In the studies reported in this disclosure, however, the a-Si was intrinsic (i-Si).

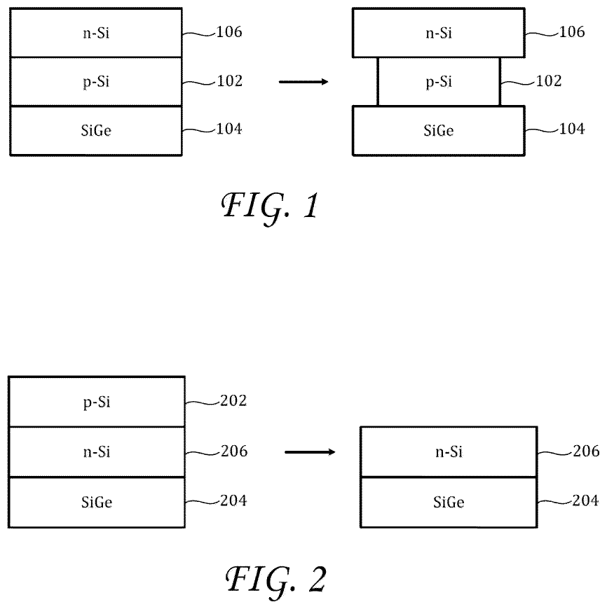

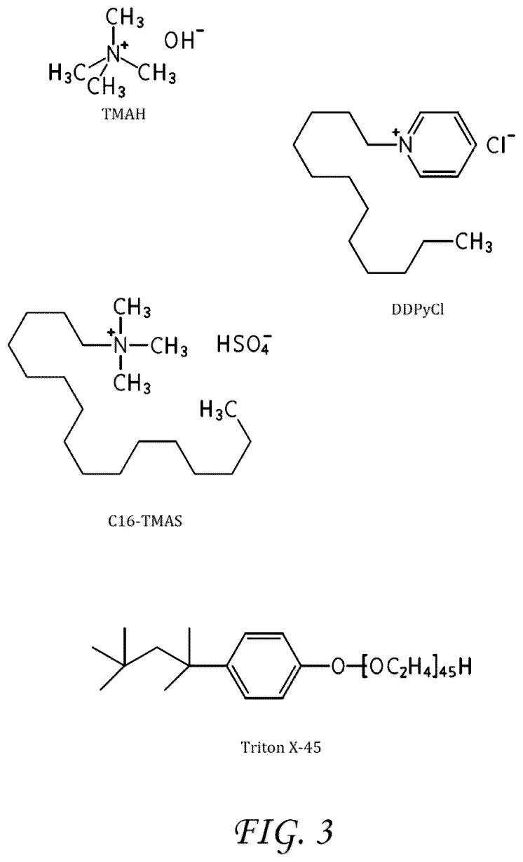

The skilled reader will appreciate that dopant densities in silicon for integrated-circuit fabrication rarely exceed 0.01% by mass. Accordingly, selective etching of p-type silicon (p-Si) in the presence of n-type silicon (n-Si), for example, is more challenging than selective etching of materials in which every etched atom is chemically distinct. Turning now to the drawings, FIGS. 1 and 2 illustrate example applications of etchant compositions and methods disclosed herein.

FIG. 1 shows aspects of an example lateral resection of an epitaxial p-Si layer 102, which is formed on an SiGe layer 104. Epitaxial n-Si layer 106, is formed on top of the epitaxial p-Si layer. The etching is achieved via wet-etch processing with p-Si and n-Si surfaces exposed concurrently to the etchant composition. As shown in the drawing, the n-Si, survives the etching with very little dimensional change, whereas the p-Si layer is significantly reduced in width.

FIG. 2 shows aspects of complete removal of an epitaxial p-Si layer 202 formed over epitaxial n-Si layer 206, which is formed on SiGe layer 204. Because the etchant composition etches p-Si much faster than it etches n-Si, layer 206 is preserved in the process. Although FIGS. 1 and 2 illustrate selective etching of epitaxial layers, that aspect is not at all necessary. In other examples, any, some or all of the layers subject to selective etching may be deposited non-epitaxially—e.g., on a glassy layer, such as amorphous SiO₂.

As noted hereinabove, wet-etch processing employs certain etchant compositions for removal of material in unprotected areas of a wafer or die. The etchant compositions are chosen based upon the rate of etching target material relative to one or more collateral materials that also may be present on the surface to be etched. Unless otherwise specified herein, the term “collateral material” is a material that is different from n-type silicon. The collateral material may be present on the surface to be etched. The collateral material may be adjacent or non-adjacent to n-type silicon, as long as the collateral material is present on the surface to be etched. In addition, in this disclosure the target material is, for example, a semiconductor of a particular dopant type or dopant level. An example collateral material may be the same semiconductor of a different dopant type or of a higher or lower dopant density of the same dopant type. Other collateral materials may include the same semiconductor presenting a different crystal face (e.g., 100 versus 111), a different semiconductor (e.g., Ge versus Si), dielectrics such as silicon oxide (SiO₂) and silicon nitride (Si₃N₄), cured photoresist (which comprises one or more cross-linked polymers), and various additive structures (e.g., metal, metal oxide, or epitaxial semiconductor features) formed on the semiconductor wafer or die surface. Such metal features may include aluminum, copper, tungsten, molybdenum, cobalt, tantalum, and gold, among others.

TABLE 1
A. Effect on p-Si, poly-Si, and n-Si etch rates of the organic solvent and surfactant in the etchant composition,
and on the temperature of the etchant composition. The immersion time in the etchant composition was 60 seconds in all
comparative etchant compositions Cx (in which x represents an integer of 1 to 9. For example, Cx represents C1 to C9 to Table 1.).

| | etchant | organic | surfactant | | p-Si | poly-Si | n-Si | p-Si/n-Si | poly-Si/n-Si |
|---|---|---|---|---|---|---|---|---|---|
| | (% by | solvent | (ppm by | temp | etch rate | etch rate | etch rate | relative | relative |
| composition | mass) | (% by mass) | mass) | (° C.) | (nm/min) | (nm/min) | (nm/min) | etch rate | etch rate |
| C1 | TMAH(5) | — | — | 25 | 120 | 180 | 220 | 0.5 | 0.8 |
| C2 | TMAH(5) | — | — | 70 | 400 | 650 | 750 | 0.5 | 0.9 |
| C3 | KOH(10) | DMSO(20) | — | 70 | 400 | 650 | 700 | 0.6 | 0.9 |
| C4 | TMAH(5) | DMSO(20) | — | 70 | 350 | 500 | 650 | 0.5 | 0.8 |
| C5 | TMAH(5) | PGMEA | — | 70 | 320 | 450 | 550 | 0.6 | 0.8 |
| | | (10) | | | | | | | |
| C6 | TMAH(5) | — | C16-TMAS | 70 | — | 100 | 120 | — | 0.8 |
| | | | (100) | | | | | | |
| C7 | TMAH(5) | — | C12-TMACI | 70 | — | 200 | 220 | — | 0.9 |
| | | | (100) | | | | | | |
| C8 | TMAH(5) | — | C6-TMAS(100) | 70 | — | 500 | 600 | — | 0.8 |
| C9 | TMAH(5) | — | Triton X-45 | 70 | — | 70 | 120 | — | 0.6 |
| | | | (100) | | | | | | |

B. Effect on p-Si, poly-Si, and n-Si etch rates of the organic solvent and surfactant in the etchant composition, and on
the temperature of the etchant composition. The immersion time in the etchant composition was 60 seconds in all examples.

| | etchant | organic | surfactant | | p-Si | poly-Si | n-Si | p-Si/n-Si | poly-Si/n-Si |
|---|---|---|---|---|---|---|---|---|---|
| | (% by | solvent | (ppm by | temp | etch rate | etch rate | etch rate | relative | relative |
| composition | mass) | (% by mass) | mass) | (° C.) | (nm/min) | (nm/min) | (nm/min) | etch rate | etch rate |
| 1 | TMAH(5) | DMSO(20) | C16-TMAS(1) | 70 | 330 | 450 | 250 | 1.3 | 1.8 |
| 2 | TMAH(5) | DMSO(20) | C16-TMAS | 70 | 120 | 160 | 50 | 2.4 | 3.2 |
| | | | (100) | | | | | | |
| 3 | TMAH(5) | DMSO(20) | C16-TMAS | 25 | 30 | 40 | 10 | 3.0 | 4.0 |
| | | | (100) | | | | | | |
| 4 | TMAH(5) | DMSO(20) | C16-TMAS | 25 | 10 | 13 | 3 | 3.3 | 4.3 |
| | | | (10k) | | | | | | |
| 5 | TMAH(5) | DMSO(20) | DDPyCl(100) | 70 | — | 20 | 4 | — | 5.0 |
| 6 | TMAH(5) | DMSO(20) | C12-TMACI | 70 | — | 250 | 90 | — | 2.8 |
| | | | (100) | | | | | | |
| 7 | TMAH(5) | DMSO(20) | C8-TMACI(100) | 70 | — | 430 | 280 | — | 1.5 |
| 8 | TMAH(5) | DMSO(10) | C12-TMACI | 70 | — | 280 | 100 | — | 2.8 |
| | | | (100) | | | | | | |
| 9 | TMAH(5) | DMSO(40) | C12-TMACI | 70 | — | 200 | 70 | — | 2.9 |
| | | | (100) | | | | | | |
| 10 | TMAH(5) | PGMEA(10) | C12-TMACI | 70 | 200 | 230 | 70 | 2.9 | 3.3 |
| | | | (100) | | | | | | |
| 11 | TMAH(5) | PC(3) | C12-TMACI | 70 | — | 180 | 100 | — | 1.8 |
| | | | (100) | | | | | | |
| 12 | KOH(10) | DMSO(20) | C12-TMACI | 70 | — | 400 | 260 | — | 1.5 |
| | | | (100) | | | | | | |

Table 1A shows aspects of a series of comparative etchant compositions C1 through C9. Companion Table 1B shows aspects of a series of example etchant compositions 1 through 12. Each of the example etchant compositions and comparative etchant compositions is an aqueous solution. In some examples, the amount of water in an etchant composition may exceed 90% by mass.

Some etchant compositions fully consonant with this disclosure may also include one or more solvents besides water. Example organic solvents that can be used in the etchant compositions include alcohols (e.g., methanol, ethanol, n-butanol, and 2-propanol), cyclic ethers, and alcohol ethers. Etchant compositions consonant with this disclosure also includes one or more surfactants, such as neutral, cationic, or anionic surfactants (vide infra).

Accordingly, the etchant compositions of Tables 1A and 1B include certain chemical compounds as solutes in the aqueous solutions. FIG. 3 shows the molecular structures of some of the chemical compounds used in the example and comparative etchant compositions. In particular, TMAH represents tetramethyl ammonium hydroxide, DDPyCl represents 1-dodecylpyridinium chloride, and C16-TMAS represents hexadecyltrimethylammonium hydrogen sulfate. Not shown in FIG. 3 are: dodecyltrimethylammonium chloride (C12-TMACl), which has four fewer methylene units than C16-TMAS and chloride in place of the hydrogen sulfate counterion; octyltrimethylammonium chloride (C8-TMACl), which has four fewer methylene units than C12-TMACl; and hexyltrimethylammonium chloride (C6-TMACl), which has two fewer methylene units than C8-TMACl. In some examples two or more surfactants may be combined in the same etchant composition.

Each of the example etchant compositions of Table 1B includes a water-soluble etchant, a water-miscible organic solvent, and a surfactant.

In some examples the water-soluble etchant is a basic etchant. More particularly, the water-soluble etchant may comprise a quaternary ammonium hydroxide, such as tetramethylammonium hydroxide (TMAH), tetraethylammonium hydroxide (TEAH), tetra-n-butylammonium hydroxide, and the like. In some examples the water-soluble etchant may comprise an alkali-metal hydroxide, such as sodium hydroxide (NaOH) or potassium hydroxide (KOH), alkali earth metal hydroxide, such as magnesium hydroxide (Mg(OH)₂), calcium hydroxide (Ca(OH)₂), strontium hydroxide (Sr(OH)₂), barium hydroxide (Ba(OH)₂), and/or ammonium hydroxide. In addition, the preferable examples of a quaternary amine salt may include one or more of a chloride salt, a bromide salt, an acetate salt, a methyl sulfate salt, and a hydrogen sulfate salt.

In some examples at least one of the one or more water-miscible organic solvents of the etchant composition is a polar solvent. More particularly, at least one water-miscible organic solvent may be a polar, aprotic solvent. Non-limiting examples include dimethyl sulfoxide (DMSO), propylene carbonate (PC), and propylene glycol methyl ether acetate (PGMEA). Other polar, aprotic solvents include dimethylformamide (DMF), acetonitrile, acetone, and tetrahydrofuran (THF). In some examples at least a small amount of a protic solvent, such as an alcohol, a diol, a poly-ol, or an amine may be used. Examples include methanol, ethanol, 2-propanol, ethylene glycol, ethylenediamine, and the like. In some examples two or more organic solvents may be combined in the same etchant composition.

In some example etchant compositions at least one of the one or more surfactants may comprise eight or more carbon atoms per molecule. In etchant compositions which are basic (i.e., alkaline, wherein a silicon surface is charged negatively), at least one surfactant may be a cationic surfactant. In more particular examples, at least one surfactant may comprise a quaternary ammonium salt. Suitable, though non-limiting, quaternary ammonium salts are those having an octyl, dodecyl, or hexadecyl substituent on nitrogen, thereby forming an amphiphile with a cationic nitrogen head group. The nitrogen head group may be further substituted by as many as three shorter (e.g., alkyl) groups, such as methyl, ethyl, etc. Alternatively, or in addition, a cationic nitrogen heterocycle, such as a dodecylpyridinium salt, may be used. The one or more anions matched with a cationic surfactant are not particularly limited. Suitable, stable anions include chloride, bromide, hydrogen sulfate, dihydrogen phosphate, hydrogen phosphate, etc.

Example etchant compositions 1 through 12 each offer an etch rate on silicon which is sensitive to the dopant type of the silicon. The sensitivity to dopant type is shown in the sixth through the tenth column of Table 1B. The sixth column lists the etch rate in nm/min on p-Si, the seventh column lists the etch rate on poly-Si, the eighth column lists the etch rate on n-Si, and the ninth and tenth columns show the relative rates.

Subjected to conventional wet-etch chemistries, n-type Si etches somewhat more rapidly than silicon of other dopant types. This is borne out in the comparative examples of Table 1A. It is evident, however, that example etchant compositions 1 through 12 provide the opposite effect—lower etch rates on n-type Si than on p-Si and poly-Si. Thus, using the example etchant compositions herein, the etch rate is lower on n-type silicon than on p-type silicon or poly-Si.

With no intention of tying this disclosure to any particular theory, surfactants having eight or more carbon atoms per molecule may adsorb appreciably (via London forces) to freshly etched silicon of various dopant types. Surfactant adsorption may reduce the subsequent etch rates, but unequally, as the surface charge also affects the etch rate. Accordingly, the etch-rate retardation caused by the higher molecular-weight surfactant amplifies the dopant-type selectivity.

The etch rates appearing in Tables 1A and 1B were determined in the following manner. Epitaxial films of n-Si and p-Si were grown via chemical vapor deposition (CVD) on silicon-germanium (SiGe) wafers. Films of poly-Si were grown via CVD on SiO₂ substrates. Each film-coated wafer was divided into a plurality of test samples of about 1 to 10 square centimeters. For each test sample, the film thickness was measured via ellipsometry or XRF.

For each test sample, 100 milliliters (mL) of aqueous hydrogen fluoride (HF, 0.5% by mass) was dispensed into a first plastic cup and stirred magnetically at 300 revolutions per minute (rpm) at 25° C. The same volume of etchant composition was dispensed into a second plastic cup and stirred magnetically at 300 rpm, at the temperature indicated in Tables 1A or 1B. Into third and fourth plastic cups was dispensed 100 mL of de-ionized water, stirred magnetically at 300 rpm at 25° C. Each test sample was placed in the first cup for 60 seconds, then moved to the third cup for 5 seconds, then to the second cup for 60 seconds, and then to the fourth cup for 5 seconds. The samples were then dried and the film-thickness measurement by ellipsometer or XRF was repeated.

In addition, regarding the etchant composition of the present embodiment, further specific examples of preferred embodiments in terms of selectivity to p-Si, poly-Si, and n-Si are exemplified below.

In some examples, the etchant preferably contains at least one selected from the group consisting of TMAH and KOH. The content of the etchant in the etchant composition is not particularly limited, but may be preferably 1% by mass or more and 20% by mass or less. In this case, the lower limit of the content thereof is more preferably 3% by mass or more. In addition, the upper limit of the content thereof is more preferably 15% by mass or less, and even more preferably 13% by mass or less.

In some examples, the organic solvent preferably contains at least one selected from the group consisting of DMSO, PGMEA, and PC. The content of the organic solvent in the etchant composition is not particularly limited, but may be preferably 1% by mass or more and 50% by mass or less. In this case, the lower limit of the content thereof is more preferably 2% by mass or more. Furthermore, in this case, the upper limit of the content thereof is more preferably 45% by mass or less.

For example, when DMSO is contained as the organic solvent, the content of DMSO is preferably 10% by mass or more and 50% by mass or less. In this case, the upper limit of this DMSO content is more preferably 45% by mass or less, and even more preferably 40% by mass or less.

For example, when PGMEA is contained as the organic solvent, the content of PGMEA is preferably 5% by mass or more and 20% by mass or less. In this case, the upper limit of this PGMEA content is more preferably 15% by mass or less, and even more preferably 10% by mass or less.

For example, when PC is contained as the organic solvent, the content of PC is preferably 0.5% by mass or more and 10% by mass or less. In this case, the lower limit of this PC content is more preferably 1% by mass or more, and even more preferably 5% by mass or less.

The surfactant preferably contains at least one selected from the group consisting of, for example, C8-TMACl, C12-TMACl, C16-TMAS, and DDPyCl. The content of the surfactant in the etchant composition is not particularly limited, but is preferably 1 ppm by mass or more and 10 kppm by mass (10,000 ppm by mass) or less. The upper limit of this content may be 5,000 ppm by mass or less, 4,000 ppm by mass or less, 3,000 ppm by mass or less, 2,000 ppm by mass or less, 1,000 ppm by mass or less, 900 ppm by mass or less, 800 ppm by mass or less, 700 ppm by mass or less, 600 ppm by mass or less, 500 ppm by mass or less, 400 ppm by mass or less, 300 ppm by mass or less, or 200 ppm by mass or less.

One of the preferred examples of the etchant composition according to the present embodiment is an etchant composition containing a total of 1 mass % to 10 mass % of at least one selected from the group consisting of TMAH and KOH, a total of 5 mass % to 40 mass % of at least one selected from the group consisting of DMSO, PGMEA, and PC, and a total of 1 ppm by mass to 10,000 ppm by mass of at least one selected from the group consisting of C8-TMACl, C12-TMACl, C16-TMAS, and DDPyCl (however, it goes without saying that the preferred examples of the present embodiment are not limited to thereto).

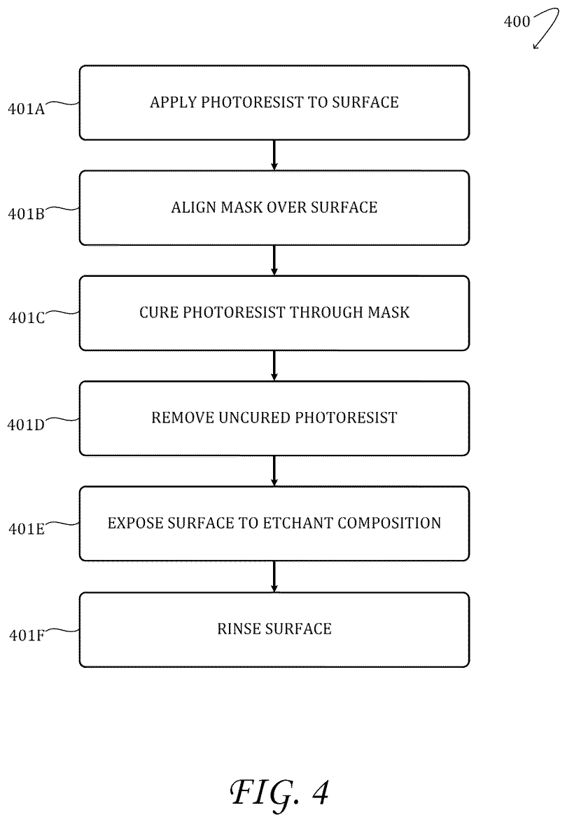

FIG. 4 shows aspects of an example method 400 for etching a surface having a first silicon region which is n-type and a second silicon region differing from the first with respect to dopant type or dopant density.

At 401A of method 400 a photoresist is applied to the surface. At 401B a mask is aligned over the surface. At 401C the photoresist is cured by UV exposure through the mask, such that no cured photoresist extends over the first silicon region or the second silicon region. At 401D the uncured photoresist is removed from the surface.

At 401E the surface is exposed to an etchant composition offering an etch rate on silicon which is sensitive to the dopant type.

In some examples the etch rate of the composition is lower on the first, n-type silicon than on silicon of another dopant type, such as the second region. Such other dopant types may include one or more of p-type silicon or poly-Si.

In one series of examples, the etchant composition comprises a water-soluble etchant, one or more water-miscible organic solvents, and one or more surfactants. As illustrated by the example etchant compositions herein, at least one of the one or more surfactants may be one to ten-thousand parts per million by mass of the etchant composition, and at least one of the one or more organic solvents is one to forty percent by mass of the etchant composition. In some examples the etch rate may be lower on the n-type silicon than on silicon of another dopant type. In some examples the surfactant may comprise eight or more carbon atoms per molecule, as noted above. In some examples the surfactant may be a cationic surfactant. In some examples the surfactant preferably contains a quaternary amine salt. Furthermore, in some examples the solvent is a polar, aprotic solvent. In some examples the etchant is a basic etchant, such as a quaternary ammonium hydroxide, an alkali-metal or alkaline-earth metal hydroxide, or ammonium hydroxide.

At 401F the surface is rinsed. In some examples the rinsing agent may comprise water. In some examples the rinsing agent may comprise an alcohol, such as isopropyl alcohol. Optionally, after the surface is rinsed and suitably dried, one or more dry-etch processes may be enacted, as desired. Optionally, the cured photoresist may be removed at this point.

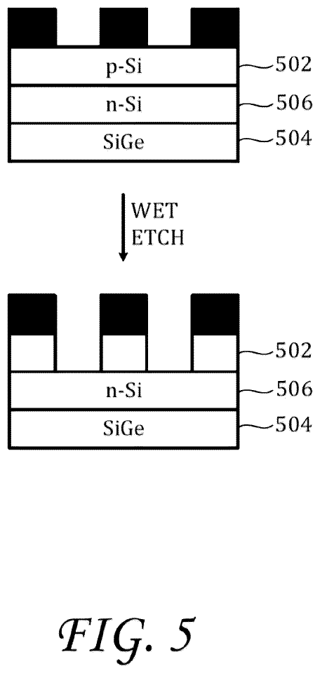

Method 400 may be used to form various types of microstructures on a semiconductor surface, such as the surface of a layered and/or patterned semiconductor. In some scenarios, the result of the application of method 400 depends upon the initial layer structure and on whether any additional etch processes, such as a dry etch, is also employed. FIGS. 5 through 7 illustrate this feature by way of example. In each drawing the starting structure includes a pattern of cured photoresist (shown in black), as would be present following step 401D of method 400.

In the structure shown in FIG. 5 an n-Si layer 506 is formed on SiGe layer 504. A p-Si layer 502 is formed on top of the n-Si layer. Due to the etchant composition used at 401E, which exhibits dopant-type selectivity (e.g., favoring p-Si etching relative to n-Si etching), the wet etch penetrates the p-Si layer and stops at the p-Si/n-Si boundary, effectively. Although n-Si is exposed to the etchant composition as the etch proceeds vertically downward, very limited etching of the n-Si occurs.

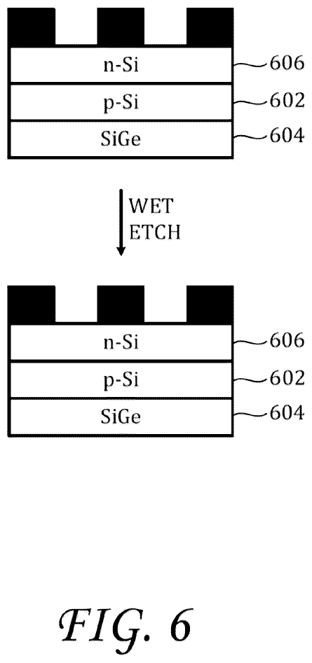

In the structure shown in FIG. 6 a p-Si layer 602 is formed on SiGe layer 604. An n-Si layer 606 is formed on top of the p-Si layer. The etchant composition used at 401E exhibits dopant-type selectivity (e.g., favoring p-Si etching relative to n-Si etching). As none of the p-Si is exposed to the etchant composition, however, very limited etching occurs.

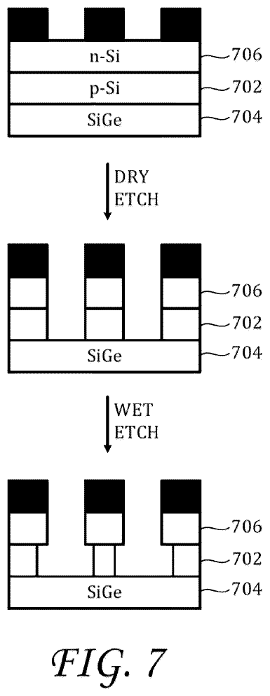

The initial structure in FIG. 7 is the same as in FIG. 6: a p-Si layer 702 is formed on SiGe layer 704. An n-Si layer 706 is formed on top of the p-Si layer. In this example, however, an anisotropic dry etch is enacted before the dopant-selective wet etch. The anisotropic dry etch etches the layer structure to the SiGe layer 704. Due to the etchant composition used at 401E, which exhibits dopant-type selectivity (e.g., favoring p-Si etching relative to n-Si etching), the wet etch acts laterally on the exposed p-Si in preference to the exposed n-Si.

By inference, the etch-rate selectivity achieved in the foregoing examples is due to the relative affinities of various surfactants for silicon, which varies according to dopant type.

No aspect of this disclosure should be interpreted in a limiting sense, for numerous variations, extensions, and omissions are equally envisaged. For instance, while the method of FIG. 4 illustrates selective etching after circuit patterning, selective etching according to the methods herein may also be useful before patterning or in between separate patterning procedures. Although the foregoing description refers specifically to etchant compositions with selectivity based on dopant type, the same or similar etchant compositions may show etch-rate selectivity based on dopant density—e.g., normal dopant density versus high dopant density versus degenerate doping. Moreover, the same or similar etchant compositions may show etch-rate sensitivity based on dopant depth—e.g., deep doping versus shallow doping.

Again, while no aspect of this disclosure is tied to any particular theory, it may be the case that the primary chemical effect of the dopant type and dopant density is to influence the space charge that develops within the semiconductor material when the semiconductor surface comes to electrostatic equilibrium with the etchant composition. Such equilibrium causes charge to accumulate, dependent on the dopant type, dopant density, and dopant depth, at the interface between the semiconductor surface and the solution. It is plausible that the relative etch rates reported in this disclosure as a function of dopant type are due to the changes in surface chemistry that result from the accumulated surface charge and are therefore extensible to dopant depth and to dopant density.

This disclosure is presented by way of example and with reference to the attached drawing figures. Components, process steps, and other elements that may be substantially the same in one or more of the figures are identified coordinately and described with minimal repetition. It will be noted, however, that elements identified coordinately may also differ to some degree. It will be further noted that the figures are schematic and generally not drawn to scale. Rather, the various drawing scales, aspect ratios, and numbers of components shown in the figures may be purposely distorted to make certain features or relationships easier to see. In addition, some overlapping explanations of the drawing figures have been omitted.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed. In some examples the terms ‘about’ and ‘approximately’, as applied to a numeric value x, expand x to include any value in a range between 0.9x and 1.1x; in some examples these terms expand x to include any value in a range between 0.95x and 1.05x.

In addition, the configurations and parameters disclosed in the present specification can be any combination unless otherwise specified. Furthermore, an upper limit and a lower limit of the values disclosed in the present specification can be any combination unless otherwise specified. In addition, in the present specification, the term “comprise” or “contain” may be replaced with “consist essentially of” and “consist of” as necessary. Further, the expression “A and/or B” means “A, B, or both”, unless otherwise specified. In the present specification, the terms “parts by mass” or “% by mass” are used, unless otherwise specified. In the present specification, the term “amount used” may refer to the content, and the term “content” may refer to the amount used.

The subject matter of the present disclosure includes all novel and non-obvious combinations and sub-combinations of the various processes, systems and configurations, and other features, functions, acts, and/or properties disclosed herein, as well as any and all equivalents thereof.

Note that, in the present specification, the expression “doing something or to do something” may refer to “process” or “step”, “process” may refer to “doing something or to do something” or “step”, and “step” may refer to “doing something or to do something” or “process”. In addition, in the present specification, the term “process” such as “step” may refer to “apparatus or unit that is configured to perform the step”, the term “apparatus” may refer to “mechanism or unit”, and the term “unit” may refer to “unit or apparatus provided for a mechanism, an apparatus, or a system”.

This disclosure also includes embodiments exemplified below.
<1> An etchant composition offering an etch rate on silicon which is sensitive to a dopant type of the silicon, the etchant composition comprising:
a water-soluble etchant;
one or more water-miscible organic solvents; and
one or more surfactants.
<2> The etchant composition of <1> wherein at least one of the one or more surfactants comprises eight or more carbon atoms per molecule.
<3> The etchant composition of <1> wherein at least one of the one or more surfactants is a cationic surfactant.
<4> The etchant composition of <1> wherein at least one of the one or more surfactants comprises a quaternary amine salt.
<5> The etchant composition of <1> wherein at least one of the one or more surfactants comprises a trimethylammonium salt having an octyl, dodecyl, or hexadecyl substituent on nitrogen.
<6> The etchant composition of <4> wherein the salt comprises one or more of a chloride salt, a bromide salt, an acetate salt, a methyl sulfate salt, or a hydrogen sulfate salt.
<7> The etchant composition of <1> wherein at least one of the one or more water-miscible solvents is a polar, aprotic solvent.
<8> The etchant composition of <1> wherein at least one of the one or more water-miscible solvents comprises dimethyl sulfoxide, propylene carbonate, or propylene glycol methyl ether acetate.
<9> The etchant composition of <1> wherein the etchant is a basic etchant.
<10> The etchant composition of <1> wherein the etchant comprises a quaternary ammonium hydroxide.
<11> A method for etching a surface having a first silicon region which is n-type and a second silicon region differing from the first with respect to dopant type, the method comprising:
exposing the surface to an etchant composition offering an etch rate on silicon which is sensitive to the dopant type, the etchant composition comprising a water-soluble etchant, one or more water-miscible organic solvents, and one or more surfactants.
<12> The method of <11> wherein at least one of the one or more surfactants is one to ten-thousand parts per million by mass of the etchant composition, and the organic solvent is one to forty percent by mass of the etchant composition.
<13> The method of <11> wherein the etch rate is lower on the n-type silicon than on silicon of another dopant type.
<14> The method of <11> wherein the surfactant comprises eight or more carbon atoms per molecule.
<15> The method of <11> wherein the surfactant is a cationic surfactant.
<16> The method of <11> wherein the solvent is a polar, aprotic solvent.
<17> The method of <11> wherein the surfactant comprises a quaternary ammonium salt.
<18> The method of <11> wherein the etchant is a basic etchant.
<19> The method of <11> wherein the etchant comprises a quaternary ammonium hydroxide.
<20> An etchant composition offering an etch rate on silicon which is sensitive to a dopant type of the silicon, the etchant composition comprising:
a basic, water-soluble etchant;
one or more water-miscible, polar, aprotic organic solvents; and
one or more cationic surfactants comprising eight or more carbon atoms per molecule.

1. An etchant composition offering an etch rate on silicon which is sensitive to a dopant type of the silicon, the etchant composition comprising:
a water-soluble etchant;
one or more water-miscible organic solvents; and
one or more surfactants.

2. The etchant composition of claim 1 wherein at least one of the one or more surfactants comprises eight or more carbon atoms per molecule.

3. The etchant composition of claim 1 wherein at least one of the one or more surfactants is a cationic surfactant.

4. The etchant composition of claim 1 wherein at least one of the one or more surfactants comprises a quaternary amine salt.

5. The etchant composition of claim 1 wherein at least one of the one or more surfactants comprises a trimethylammonium salt having an octyl, dodecyl, or hexadecyl substituent on nitrogen.

6. The etchant composition of claim 4 wherein the salt comprises one or more of a chloride salt, a bromide salt, an acetate salt, a methyl sulfate salt, or a hydrogen sulfate salt.

7. The etchant composition of claim 1 wherein at least one of the one or more water-miscible solvents is a polar, aprotic solvent.

8. The etchant composition of claim 1 wherein at least one of the one or more water-miscible solvents comprises dimethyl sulfoxide, propylene carbonate, or propylene glycol methyl ether acetate.

9. The etchant composition of claim 1 wherein the etchant is a basic etchant.

10. The etchant composition of claim 1 wherein the etchant comprises a quaternary ammonium hydroxide.

11. A method for etching a surface having a first silicon region which is n-type and a second silicon region differing from the first with respect to dopant type, the method comprising:
exposing the surface to an etchant composition offering an etch rate on silicon which is sensitive to the dopant type, the etchant composition comprising a water-soluble etchant,
one or more water-miscible organic solvents, and one or more surfactants.

12. The method of claim 11 wherein at least one of the one or more surfactants is one to ten-thousand parts per million by mass of the etchant composition, and the organic solvent is one to forty percent by mass of the etchant composition.

13. The method of claim 11 wherein the etch rate is lower on the n-type silicon than on silicon of another dopant type.

14. The method of claim 11 wherein the surfactant comprises eight or more carbon atoms per molecule.

15. The method of claim 11 wherein the surfactant is a cationic surfactant.

16. The method of claim 11 wherein the solvent is a polar, aprotic solvent.

17. The method of claim 11 wherein the surfactant comprises a quaternary ammonium salt.

18. The method of claim 11 wherein the etchant is a basic etchant.

19. The method of claim 11 wherein the etchant comprises a quaternary ammonium hydroxide.

20. An etchant composition offering an etch rate on silicon which is sensitive to a dopant type of the silicon, the etchant composition comprising:
a basic, water-soluble etchant;
one or more water-miscible, polar, aprotic organic solvents; and
one or more cationic surfactants comprising eight or more carbon atoms per molecule.
